(19) United States
(12) Patent Application Publication
(10) Pub. No.: US 2026/0181988 A1
(43) Pub. Date: Jun. 25, 2026

(54) METHOD AND SYSTEM FOR TRANSISTOR WITH COMBINED SOURCE AND WELL CONTACT

(71) Applicant: Diodes Incorporated, Plano, TX (US)

(72) Inventor: Jennifer A. Driscoll, Plano, TX (US)

(73) Assignee: Diodes Incorporated, Plano, TX (US)

(21) Appl. No.: 19/066,579

(22) Filed: Feb. 28, 2025

Related U.S. Application Data
(60) Provisional application No. 63/736,524, filed on Dec. 19, 2024.

(51) Int. Cl. H10D 64/23; H01L 21/768; H10D 30/01; H10D 30/65; H10D 64/66

(52) U.S. Cl. CPC H10D 64/257; H10D 30/0281; H10D 30/657; H10D 64/665; H10D 64/667; H10W 20/076

(57) ABSTRACT

A metal-oxide-semiconductor (MOS) transistor includes a substrate including a well region, an insulator layer coupled to the substrate, and a source including a source region, a source contact passing through the insulator layer and the source region, and an ohmic contact disposed in the well region. The MOS transistor also includes a gate region including a gate insulator layer and a gate contact and a drain including a drain region and a drain contact passing through the insulator layer to the drain region. The MOS transistor can be an LDMOS transistor, for example, an LNDMOS or LPDMOS transistor.

### CROSS-REFERENCES TO RELATED APPLICATIONS

This application claims priority to U.S. Provisional Patent Application No. 63/736,524, filed on Dec. 19, 2024, and entitled “METHOD AND SYSTEM FOR TRANSISTOR WITH COMBINED SOURCE AND WELL CONTACT,” the disclosure of which is hereby incorporated by reference in its entirety.

### BACKGROUND OF THE INVENTION

Transistors are widely used in a variety of electronic devices. Metal-oxide-semiconductor (MOS) transistors are commonly used transistors. Laterally diffused MOS (LDMOS) transistors can provide high power density and linearity, high breakdown voltage, and other advantages. Despite the progress made in the area of MOS and LDMOS transistors, there is a need in the art for improved methods and systems related to transistor design and fabrication.

### SUMMARY OF THE INVENTION

Embodiments of the present disclosure relate to transistor architecture and fabrication processes. More particularly, embodiments of the present invention provide methods and systems for LDMOS transistors with a combined source and well connection. In a particular embodiment, an array of transistors includes LDMOS transistors that provide an electrical connection to both the source and the body (i.e., the well), reducing the specific on resistance in comparison with conventional transistors. Embodiments of the present invention are applicable to both LDMOS and MOS transistors.

As described more fully herein, embodiments of the present invention provide methods and structures that improve the performance of an n-type LDMOS transistor using a combined source and well connection achieved by etching vertically through several device layers and junctions.

According to an embodiment of the present invention, a metal-oxide-semiconductor (MOS) transistor is provided. The MOS transistor includes a substrate including a well region, an insulator layer coupled to the substrate, and a source including a source region a source contact passing through the insulator layer and the source region, and an ohmic contact disposed in the well region. The MOS transistor also includes a gate region including a gate insulator layer and a gate contact and a drain including a drain region and a drain contact passing through the insulator layer to the drain region.

According to an embodiments of the present invention, a transistor array is provided. The transistor array includes a plurality of metal-oxide-semiconductor (MOS) transistors forming the transistor array, each of the plurality of MOS transistors including a source region having a source contact, well or well contact adjacent the source region, a gate region having a gate contact, and a drain region having a drain contact. The source contact electrically connects the source region and the well contact. The well contact can be disposed below the source region, and the source contact can pass through the source region to the well contact. Each of the plurality of MOS transistors can be LDMOS transistors. In some embodiments the transistor array includes a first metal interconnect electrically connecting each of the plurality of source contacts and a second metal interconnect electrically connecting each of the plurality of drain contacts.

According to a particular embodiment of the present invention, a method of fabricating an n-type laterally diffused metal oxide semiconductor (LNDMOS) device is provided. The method includes providing a substrate including a well region, forming a gate structure on the substrate, and performing a first ion implantation process to form a source region and a drain region. The method further includes forming a silicide layer on the substrate and forming an insulation layer on the silicide layer. The method further includes etching a first opening through the insulation layer to the silicide layer, and extending the first opening to pass through the source region into the well region. The method further includes performing a second ion implantation process to form an ohmic contact, forming a source contact in the first opening, performing a chemical mechanical polishing (CMP) process to planarize the source contact, etching a second opening through the insulation layer to the silicide layer, and forming a drain contact in the second opening.

According to another particular embodiment of the present invention, a method of fabricating a p-type laterally diffused metal oxide semiconductor (LPDMOS) device is provided. The method includes providing a substrate (e.g., an n-type substrate) including a n-type well region, forming a gate structure on the substrate, and performing a first ion implantation process to form a source region and a drain region. The method further includes forming a silicide layer on the substrate, and forming an insulation layer on the silicide layer. The method further includes etching a first opening through the insulation layer to the silicide layer, and extending the first opening to pass through the source region into the n-type well region. The method further includes performing a second ion implantation process to form an ohmic contact, e.g., an ohmic contact to the well, forming a source contact in the first opening, performing a chemical mechanical polishing (CMP) process to planarize the source contact, etching a second opening through the insulation layer to the silicide layer, and forming a drain contact in the second opening.

In some embodiments, fabricating the LPDMOS device can include etching a third opening through the insulation layer to the silicide layer and forming a second source contact in the third opening. Etching the second opening and the third opening can be performed concurrently. Forming the source contact in the first opening can be performed prior to forming the second source contact. In some embodiments, forming the source contact comprises depositing a contact liner in the first opening and depositing a contact plug on the contact liner to fill the first opening. Extending the first opening can form a taper region in the insulation layer. Performing the CMP process can remove the taper region. Performing the CMP process can similarly remove an upper portion of the insulating layer. The first opening can pass through the silicide layer and into the well region. Forming the drain contact can be performed after forming the source contact.

Numerous benefits are achieved by way of the present invention over conventional techniques. For example, embodiments of the present invention provide a direct contact to the body (i.e., the well) that reduces the specific on resistance (RSP) of the device by reducing the size of the source/well tie regions. Additionally, some embodiments reduce the polysilicon to polysilicon spacing since embodiments utilize lithography processes with reduced layer alignment tolerances and improved topography. Moreover, embodiments of the present invention improve the LDMOS ruggedness and safe operating area (SOA) by integrating a well tie into every source connection in some implementations in comparison with conventional approaches in which only a fraction of source connections incorporate well ties. Furthermore, the fabrication methods discussed herein improve and simplify the photolithography process by eliminating the use of resist pillars and slits, thereby allowing the source region to be completely n+ without traditional photolithography challenges caused by the resist pillars and slits. Using these photolithography processes, process complexity, variation, concerns, risks, and complications associated with conventional processes are reduced. These, and other embodiments of the invention, along with many of its advantages and features are described in more detail in conjunction with the text below and attached figures.

### BRIEF DESCRIPTION OF THE DRAWINGS

FIG. 1A is a simplified cross-sectional diagram of an LDMOS transistor having a combined source and well contact according to an embodiment of the present invention.

FIG. 1B is a simplified cross-sectional diagram of an LDMOS transistor having a second source contact according to an embodiment of the present invention.

FIG. 2A is a simplified plan view of an LDMOS transistor array having source regions including a source contact to the source and the well according to an embodiment of the present invention.

FIG. 2B is a simplified plan view of an LDMOS transistor array having source contacts illustrated in FIG. 2A and a second source contact according to an embodiment of the present invention.

FIG. 2C is a simplified plan view of an LDMOS transistor array having source regions including shared source contacts to the source and the well according to an embodiment of the present invention.

FIG. 3 is a simplified flowchart of a method of fabricating an n-type LDMOS transistor having source regions including a source contact to the source and the well according to an embodiment of the present invention.

FIGS. 4A-15 are simplified cross-sectional diagrams illustrating stages of fabrication of an LDMOS transistor having source regions including a source contact to the source and the well according to an embodiment of the present invention.

FIG. 16A is a simplified cross-sectional diagram illustrating a source contact and a gate region of an n-type LDMOS transistor according to an embodiment of the present invention.

FIG. 16B is a simplified cross-sectional diagram illustrating a source contact and a gate region of an p-type LDMOS transistor according to an embodiment of the present invention.

The same or similar components are denoted with the same reference signs in the drawings and detailed description. Several embodiments of the present disclosure will be immediately understood from the following detailed description with reference to the accompanying drawings.

### DETAILED DESCRIPTION OF SPECIFIC EMBODIMENTS

Embodiments of the present disclosure relate to transistor architecture and fabrication processes. More particularly, embodiments of the present invention provide methods and systems for LDMOS transistors with a combined source and well connection. In a particular embodiment, an array of transistors includes LDMOS transistors that provide an electrical connection to both the source and the body (i.e., the well), reducing the specific on resistance in comparison with conventional transistors. Embodiments of the present invention are applicable to both LDMOS and MOS transistors.

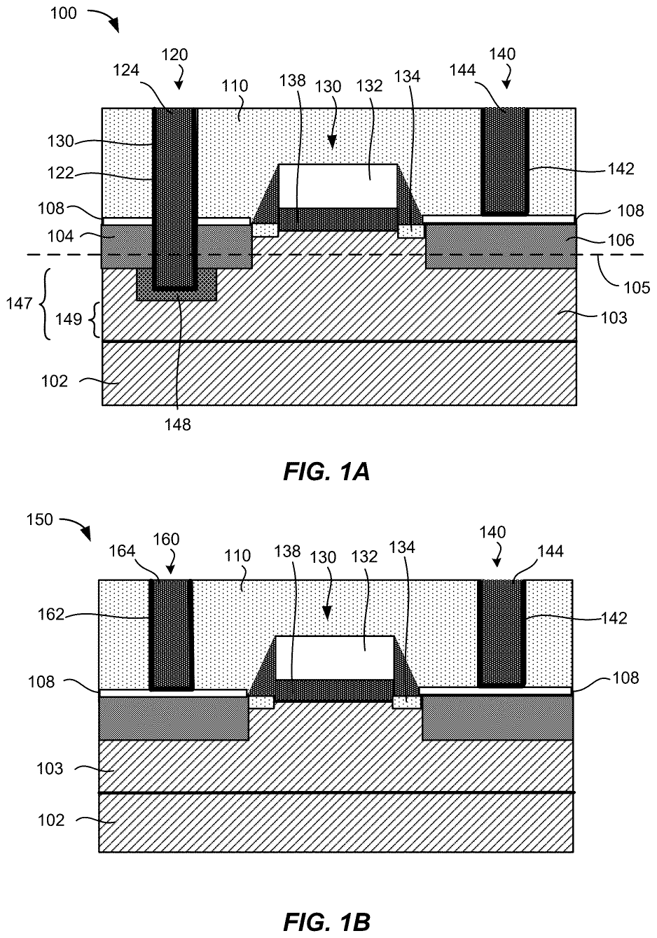

FIG. 1A is a simplified cross-sectional diagram of an LDMOS transistor 100 having a combined source and well contact according to an embodiment of the present invention. As discussed more fully below, embodiments of the present invention provide a transistor architecture or structure with different contact tungsten plug connections on the source and the drain. The drain plug connection can be made to a silicide layer. The source plug connection extends deeper than the silicide surface, through the source junction doping, and into the transistor well region, thereby forming a combined source and well connection.

Referring to FIG. 1A, substrate 102, for example, a silicon substrate, is utilized to support source region 104 and drain region 106. The substrate 102 includes a well region 103, for example, a p-doped layer formed by an ion implantation and anneal process. In an n-type LDMOS device, source region 104 and drain region 106 are typically formed using an ion implantation process for forming n+ regions although other methods of formation are included within the scope of the present invention. A silicide layer 108 is present in contact with source region 104 and drain region 106. The silicide layer 108 can be a cobalt silicide layer, a titanium silicide layer, or the like. A gate region 130 is formed between source region 104 and drain region 106 and includes a lightly doped drain source (LDD) 134 and a gate oxide insulator layer 138 that extends below a gate contact 132.

A source contact 120, which includes source contact liner 122 and source contact plug 124, is electrically separated from drain contact 140, which includes drain contact liner 142 and drain contact plug 144, by insulator layer 110. The source contact 120 extends through source region 104 (i.e., to a location below source region 104) into well region 103 and is connected to the substrate 102 by an ohmic contact 148 (also referred to as the well contact). Thus, source contact 120 provides a combined source and well connection since it electrically connects both source region 104 and well region 103 by the ohmic contact 148. The source region 104 may be positioned a first predetermined distance 147 from the substrate 102, while the ohmic contact 148 is positioned a second predetermined distance 149 from the substrate which is less than the first predetermined distance 147. It should be noted that this contact extends past the source implant, and stop in the well, before reaching the substrate.

It should be noted that the n-type LDMOS device illustrated in FIG. 1 differs from conventional devices since source contact 120 is present in the same plane as source region 104, i.e., between portions of source region 104 measured in the horizontal plane. In conventional devices, a p+ implant region would be present between portions of source region 104 and in electrical contact, via the ohmic contact 148, with well region 103. In contrast, embodiments of the present invention utilize a source contact that extends through source region 104 to make contact, via the ohmic contact 148, with well region 103, thereby providing a metal between portions of the source region rather than a semiconductor material. As a result, in substrate plane 105, i.e., a plane parallel to the processing surface of the substrate, the source region includes both semiconductor material (i.e., source region 104) and metal (the portion of source contact 120 present at substrate plane 105) since source contact 120 passes through source region 104 into well region 103.

Referring once again to FIG. 1A, drain contact 140 passes through insulator layer 110 and drain contact liner 142 makes electrical contact with silicide layer 108 and drain region 106 as a result. Accordingly, drain contact 140 including drain contact plug 144 and drain contact liner 142 provides electrical connectivity to drain region 106.

In contrast with fabrication processes that involve the definition a small region of p+ source/drain implant, which requires sufficient spacing between polysilicon lines to define a pillar of resist to block the n+ source/drain implant where the p+ contact to the well (i.e., body) will be located, embodiments define a slit in the n+ photoresist for the p+ source/drain implant.

Although embodiments of the present invention are described in relation to an n-type LDMOS transistor, this is not required and embodiments include other transistor architectures, including p-type LDMOS transistors and MOS transistors (e.g., n-type MOS (NMOS) and p-type MOS (PMOS)) transistors).

FIG. 1B is a simplified cross-sectional diagram of an LDMOS transistor having a second source contact according to an embodiment of the present invention. The LDMOS transistor 150 illustrated in FIG. 1B shares common elements with the LDMOS transistor 100 illustrated in FIG. 1A and the description provided in relation to the LDMOS transistor 100 is applicable to the LDMOS transistor 150 as appropriate. Referring to FIG. 1B, second source contact 160, which includes second source contact liner 162 and second source contact plug 164, is electrically separated from drain contact 140, which includes drain contact liner 142 and drain contact plug 144, by insulator layer 110. In contrast with source contact 120 illustrated in FIG. 1A, the second source contact 160, like drain contact 140 passes through insulator layer 110, but terminates at silicide layer 108, where second source contact liner 162 makes electrical contact with silicide layer 108 and source region 104 as a result.

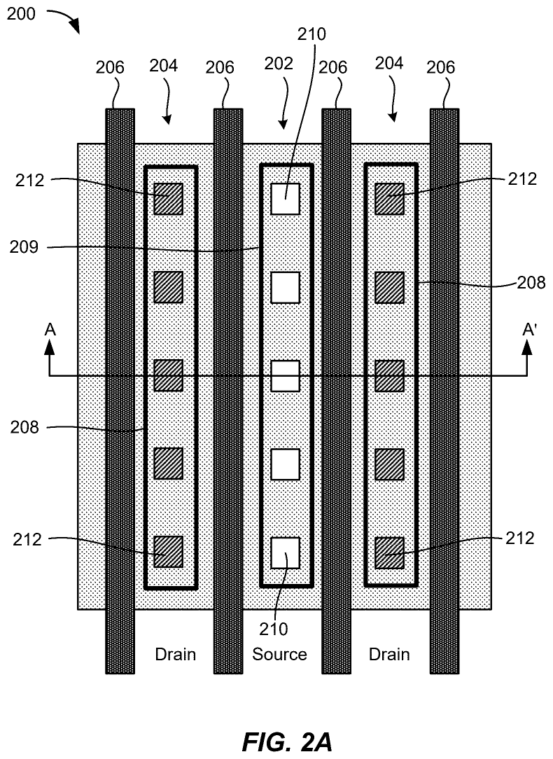

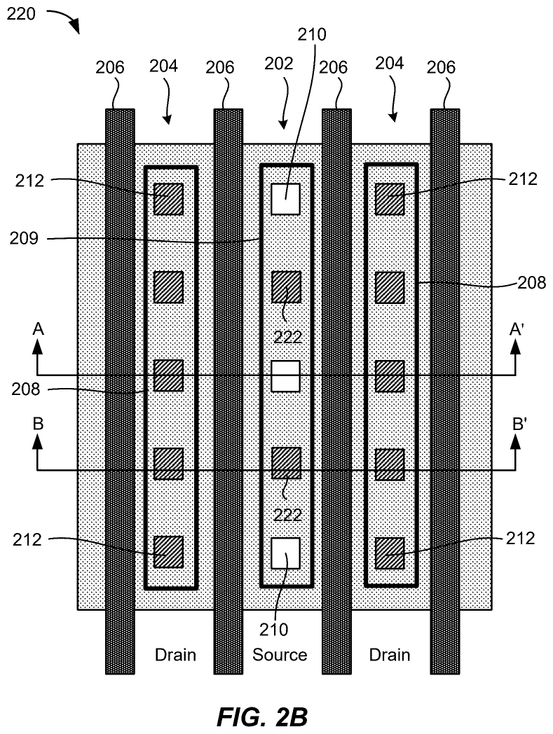

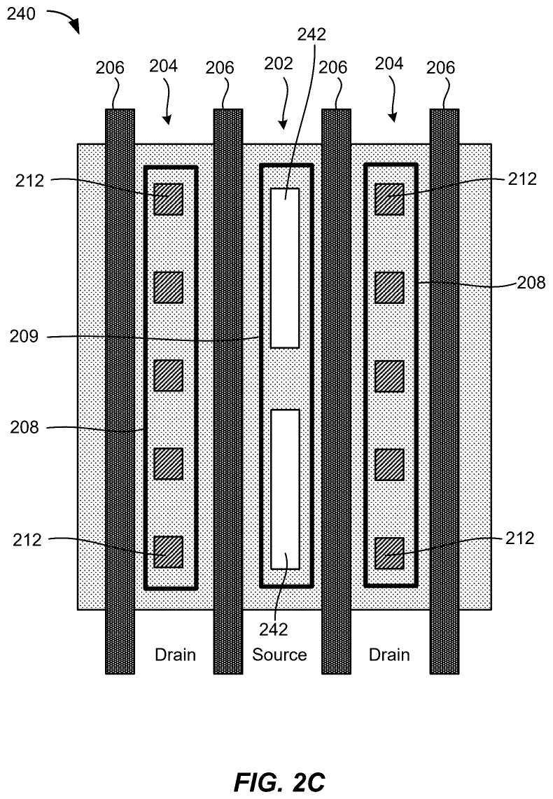

As described more fully in relation to FIG. 2B, embodiments of the present invention can utilize both source contact 120 illustrated in FIG. 1A and second source contact 160 illustrated in FIG. 1B. In some architectures, all of the source contacts are implemented using source contact 120, whereas in other architectures, a fraction of the source contacts are implemented using source contact 120 and the remainder of the source contacts are implemented using second source contact 160.

FIG. 2A is a simplified plan view of an LDMOS transistor array having source regions including a source contact to the source and the well according to an embodiment of the present invention. FIG. 2A thus illustrates surface regions of the source contact 210 and drain contact 212, each of source contact surface region and the drain contact surface region are disposed above the insulator layer (110 as shown in FIGS. 1A and 1B). In FIG. 2A, the LDMOS transistor array 200 includes five transistors, but this is merely exemplary and a larger number of LDMOS transistors can be included in the LDMOS transistor array 200. As an example, the source contact 210 and drain contacts 212 of the transistors are illustrated. Thus, the LDMOS transistor array 200 includes a source column 202 and a set of drain columns 204 separated by polysilicon lines 206, where the polysilicon lines 206 form a polysilicon layer of the LDMOS transistor.

In the LDMOS transistor array 200 illustrated in FIG. 2A, each of the source contacts of the LDMOS transistors is implemented using source contact 120 illustrated in FIG. 1A. As a result, each source contact extends through source region and into well region 103, thereby providing a combined source and well connection that electrically connects both the source region and the well region of the transistor. Accordingly, cross-section A-A′ in FIG. 2A corresponds to the cross-section illustrated in FIG. 1A.

FIG. 2A illustrates multiple metal interconnect layers electrically connecting contacts. Drain metal interconnects 208 provide for electrical connectivity between the drain contacts 212. Source metal interconnect 209 provides for electrical connectivity between the source contacts 210. Since every source contact 210 is electrically connected to the well region, the efficiency of the device is improved in comparison to designs in which source contacts are electrically connected by a metal interconnect.

FIG. 2B is a simplified plan view of an LDMOS transistor array having source contacts illustrated in FIG. 2A and a second source contact according to an embodiment of the present invention. The LDMOS transistor array 220 illustrated in FIG. 2B shares common elements with the LDMOS transistor array 200 illustrated in FIG. 2A and the description provided in relation to the LDMOS transistor array 200 is applicable to the LDMOS transistor array 220 as appropriate.

Referring to FIG. 2B, a subset of the transistors making up the LDMOS transistor array 220 utilize a source contact that passes through the insulator layer and the doped source region to the well region, thereby providing a source contact that electrically connects the doped source region to the well region. This contrasts with the LDMOS transistor array 200 illustrated in FIG. 2A in which all of the source contacts electrically connect the doped source region to the well region.

As illustrated in FIG. 2B, second source contact 222, which is implemented as second source contact 160 illustrated in FIG. 1B, is utilized for every other transistor, alternating with transistors using source contact 210, which is implemented as source contact 120 illustrated in FIG. 1A. As a result, an array of transistors is provided that alternately uses source contact 210 and second source contact 222. Accordingly, cross-section A-A′ in FIG. 2B corresponds to the cross-section illustrated in FIG. 1A and cross-section B-B′ in FIG. 2B corresponds to the cross-section illustrated in FIG. 1B.

In other embodiments, the layout of the source contact 210 and the second source contact 222 is varied, with several contacts of each type being utilized adjacent to each other. Accordingly, the layout illustrated in FIG. 2B is merely exemplary and embodiments of the present invention are not limited to this particular layout. One of ordinary skill in the art would recognize many variations, modifications, and alternatives.

Thus, embodiments of the present invention provide LDMOS transistor arrays in which some of the source contacts (e.g., source contact 210) electrically connect the doped source region to the well region while other source contacts (e.g., second source contact 222) only contact the doped source region.

FIG. 2C is a simplified plan view of an LDMOS transistor array having source regions including shared source contacts to the source and the well according to an embodiment of the present invention. The LDMOS transistor array 240 illustrated in FIG. 2C shares common elements with the LDMOS transistor array 200 illustrated in FIG. 2A and the description provided in relation to the LDMOS transistor array 200 is applicable to the LDMOS transistor array 240 as appropriate. In the embodiment illustrated in FIG. 2C, source contacts 242 are implemented as slits, i.e., rectangular features in plan view, rather than holes as illustrated in FIGS. 2A and 2B. The slits illustrate that the surface region of the source contacts 242 may have a larger surface area than the surface region of the drain contacts 212. The number of drain contacts corresponding to each of the source contacts 242 can be varied as appropriate to the particular application. Accordingly, embodiments of the present invention utilize rectangular and square features as well as features in the shapes of slits and holes. One of ordinary skill in the art would recognize many variations, modifications, and alternatives.

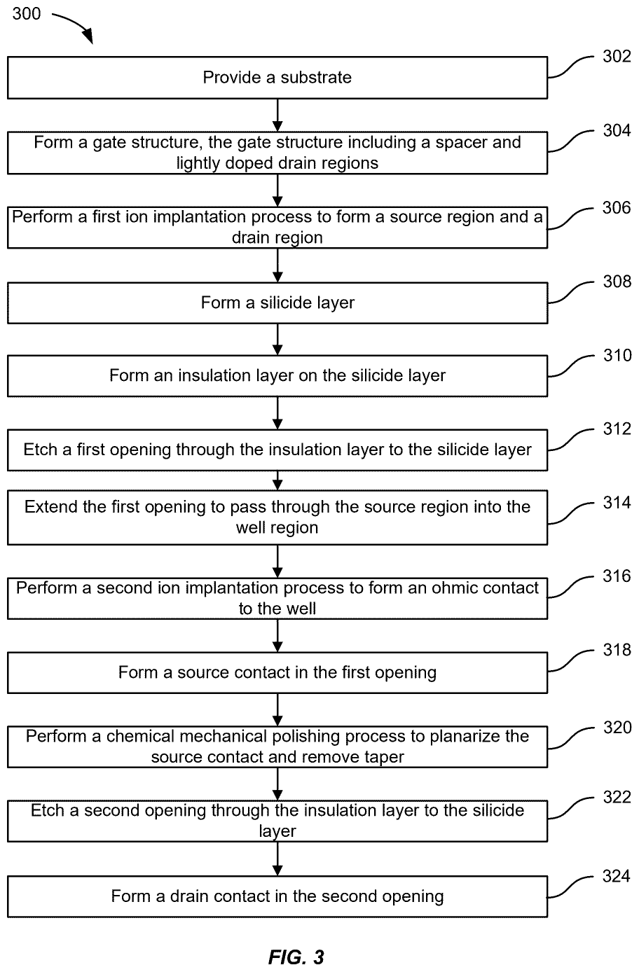

FIG. 3 is a simplified flowchart of a method of fabricating an n-type LDMOS transistor having source regions including a source contact to the source and the well according to an embodiment of the present invention.

In summary and as described in relation to FIG. 3, contact etching is performed using two separate masking, etching, filling, etc., processes. The drain contact etch process is a contact etch using a plasma oxide etch tool that stops the etch on the silicon/silicide layer. The source contact etch process uses the plasma oxide etch tool that stops the etch on the silicon/silicide layer. The wafer is then transferred to a transformer-coupled plasma (TCP) etch tool that uses a chlorine-based chemistry (e.g., Cl₂/BCl₃) to etch through the silicide layer and the n+ source/drain region into the underlying p-type body region. The same mask can be used during the etching process performed in the plasma oxide etch tool as well as the TCP etch tool.

The wafer is then implanted with a low energy, high dose p+ implant to reduce the contact resistance, then filled with titanium and titanium nitride (Ti/TiN) contact liner and tungsten to form an ohmic contact. A photoresist strip process is utilized, either before or after the implantation process. As described more fully below, the tungsten polish time is extended to remove a surface oxide taper that occurs as a result of the additional silicon etch process. The initial dielectric thickness is increased to account for the tungsten polish removal. The wafer can then be processed through a standard contact etch process, resist stripped, and then filled with Ti/TiN contact liner and tungsten to form the ohmic contact. It should be noted that the drain contact can be formed before the source contact or after the source contact. In the embodiment illustrated in FIG. 3, the drain contact is formed after the source contact, although that is not required by embodiments of the present invention.

Referring to FIG. 3, the method 300 includes providing a substrate (302) and forming a gate structure including a spacer and LDD regions (304). The gate structure can be formed by performing a thermal wet or dry oxidation process. Polysilicon is deposited, patterned, and etched, low doped (LDD) implants are done, and a nitride or oxide spacer is formed on the sidewalls of the polysilicon.

The method 300 also includes performing a first ion implantation process to form a source region and a drain region (306). The source region and drain region can be formed with the same n+ implant. The method 300 further includes forming a silicide layer (308) and forming an insulation layer on the silicide layer (310). The silicide layer can be formed by depositing a silicide metal on a clean surface, heating the wafer using a rapid thermal processing (RTP) process to form the silicide on exposed silicon surfaces, selectively removing the unreacted metal in a wet etch process, then heating the wafer again to complete the formation of the silicide. The silicide layer can comprise cobalt, platinum, titanium, or other materials, e.g., silicide metals, utilized in semiconductor manufacturing.

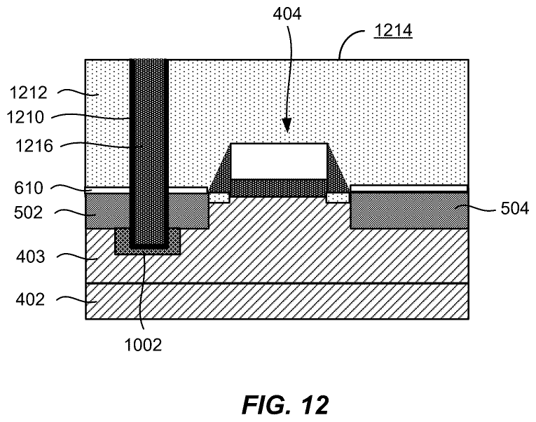

The method 300 further includes etching a first opening through the insulation layer to the silicide layer (312), extending the first opening (314), and performing a second ion implantation process to form an ohmic contact to the well region (316). Extending the first opening (314) can include using an additional etch process so that the first opening passes through the silicide layer and source region into the well. Extending the first opening (314) can form a taper region in the insulation layer as the photoresist mask erodes. As discussed in relation to FIG. 12 below, this taper region can be removed during a subsequent planarization process that removes an upper portion of the insulating layer. The first opening passes through the silicide layer into the substrate.

In some embodiments, the second ion implantation process is performed at high dose and low energy to produce a suitable p-type doping density in the well region.

Additionally, the method 300 includes forming a source contact in the first opening (318), performing a chemical mechanical polishing (CMP) process to planarize the source contact and remove a taper (320), etching a second opening through the insulation layer to the silicide layer (322), and forming a drain contact in the second opening (324). The drain contact can be formed before or after the source contact. The source contact can include a contact liner and a contact plug, for example, a Ti/TiN contact liner deposited in the first opening followed by a tungsten plug that is deposited on the contact liner to fill the first opening.

In some embodiments, the method 300 also includes further etching a second opening through the insulation layer to the silicide layer and forming a second source contact in the second opening. Etching of the second opening (i.e., to form the second source contacts) and the further etching of the second opening (i.e., to form the drain contacts), which can also be referred to as etching of a third opening, can be performed concurrently. Thus, as illustrated in FIGS. 1B and 2B, the transistor array can include both transistors using a combined source and well connection that electrically connects both the source region and the well region of a transistor in the array as well as a standard source contact that connects to the silicide layer and the source region. Depending on the implementation, the source contact can be formed prior to forming the second source contact or the second source contact can be formed prior to forming the source contact.

Embodiments contrast with conventional fabrication processes in which two photolithography steps are utilized to block the n+ source/drain (e.g., using a pillar of photoresist) and separately form the p+ source (e.g., using a slit opening in a photoresist layer) prior to the implantation processes. As will be evident to one of skill in the art, the variable height topography and the photoresist dimensions present challenges during fabrication. As a result, the polysilicon lines 206 illustrated in FIG. 2A are generally spaced a significant distance from the source columns 202 and drain columns 204. As discussed more fully below, embodiments of the present invention reduce the complexity and wide spacing between the polysilicon lines associated with conventional designs by forming a deep contact passing through the n+ source region to the p+ well and making electrical contact to both the n+ source region and the p+ well.

It should be appreciated that the specific steps illustrated in FIG. 3 provide a particular method of fabricating an n-type LDMOS transistor having source regions including a source contact to the source and the well according to an embodiment of the present invention. Other sequences of steps may also be performed according to alternative embodiments. For example, alternative embodiments of the present disclosure may perform the steps outlined above in a different order. Moreover, the individual steps illustrated in FIG. 3 may include multiple sub-steps that may be performed in various sequences as appropriate to the individual step. Furthermore, additional steps may be added or removed depending on the particular applications. One of ordinary skill in the art would recognize many variations, modifications, and alternatives.

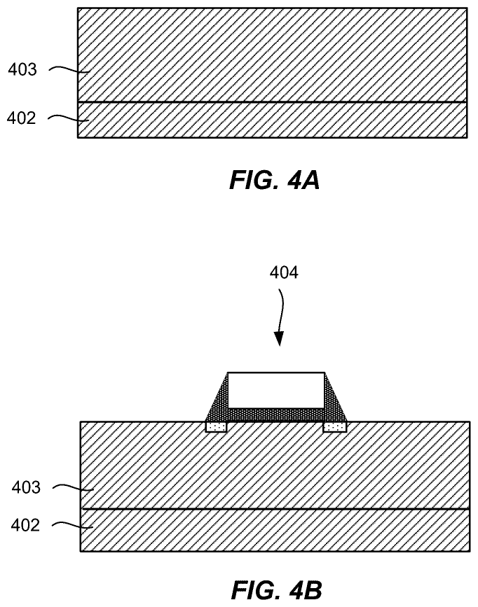

FIGS. 4A-15 are simplified cross-sectional diagrams illustrating stages of fabrication of an LDMOS transistor having source regions including a source contact to the source and the well according to an embodiment of the present invention.

FIG. 4A is a simplified cross-sectional diagram of the LDMOS transistor at a first stage of fabrication according to an embodiment of the present invention. As shown in FIG. 4, a substrate 402, for example, a silicon substrate, is provided. The substrate 402 includes a well 403, for example, a p-doped layer formed by an ion implantation and anneal process.

FIG. 4B is a simplified cross-sectional diagram of the LDMOS transistor at a second stage of fabrication according to an embodiment of the present invention. As shown in FIG. 4B, a gate structure 404, also referred to as a gate region, is formed on the substrate 402 and well 403.

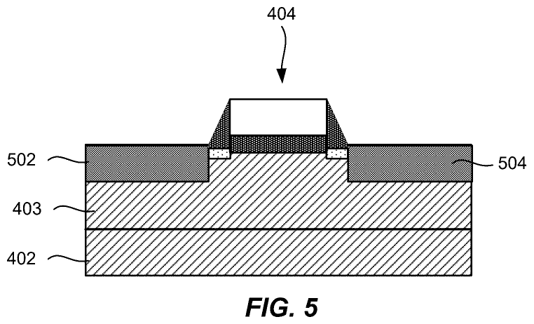

FIG. 5 is a simplified cross-sectional diagram of the LDMOS transistor at a third stage of fabrication according to an embodiment of the present invention. As illustrated in FIG. 5, an ion implantation process is utilized to form a source region 502, which can also be referred to as a doped source region, and a drain region 504, which can also be referred to as a doped drain region.

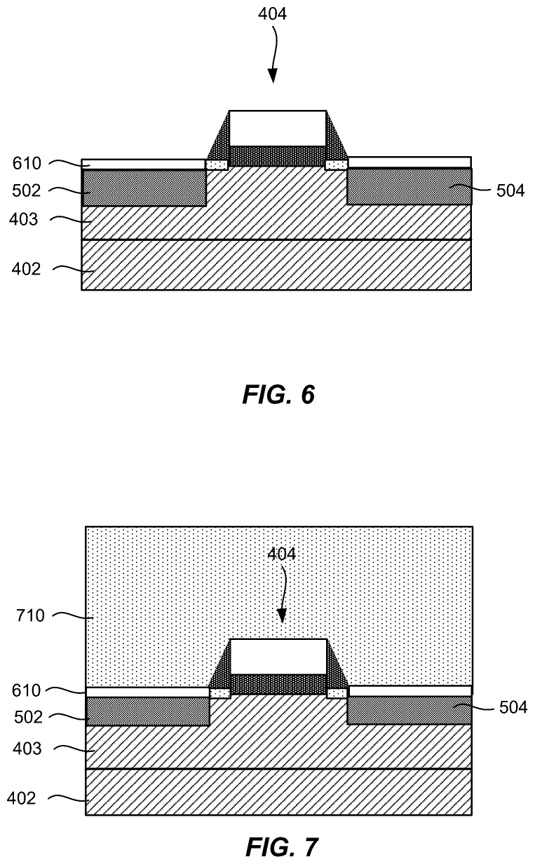

FIG. 6 is a simplified cross-sectional diagram of the LDMOS transistor at a fourth stage of fabrication according to an embodiment of the present invention. As shown in FIG. 6, the substrate 402 is processed to form silicide layer 610 (also referred to as the insulating layer). The silicide layer 610 can be a cobalt silicide layer, a titanium silicide layer, or the like.

FIG. 7 is a simplified cross-sectional diagram of the LDMOS transistor at a fifth stage of fabrication according to an embodiment of the present invention. As illustrated in FIG. 7, an insulator layer 710 is formed. The insulator layer 710 can be a silicon dioxide layer ˜1 μm thick formed using a plasma enhanced chemical vapor deposition (PECVD) and oxide CMP process. In other embodiments, other insulating materials, including SiₓN_{y}, SiOₓN_{y} or the like can be utilized. The initial thickness of insulator layer 710 is thicker than the final thickness as described more fully below in relation to FIG. 12, which describes a process in which the upper portion of insulator layer 710 is removed during a planarization process.

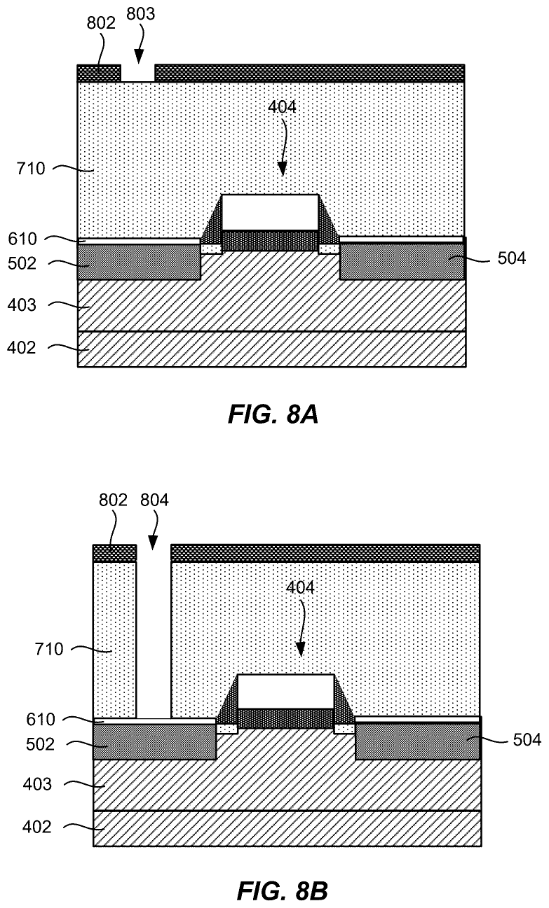

FIG. 8A is a simplified cross-sectional diagram of the LDMOS transistor at a sixth stage of fabrication according to an embodiment of the present invention. Referring to FIG. 8A, a layer of photoresist is deposited and patterned to form photoresist mask 802. An opening 803 in photoresist mask 802 will be utilized during subsequent processing to form a first opening suitable for use during source contact formation.

FIG. 8B is a simplified cross-sectional diagram of the LDMOS transistor at a seventh stage of fabrication according to an embodiment of the present invention. As illustrated in FIG. 8B, a first etch process, for example, implemented using a plasma oxide etch tool, is utilized to from first opening 804 passing through insulator layer 710 to silicide layer 610. In some embodiments, silicide layer 610 serves as an etch stop during the etch process, whereas in other embodiments, timing of the etch or other suitable process monitoring techniques are utilized to terminate the etch at the silicide layer 610. One of ordinary skill in the art would recognize many variations, modifications, and alternatives.

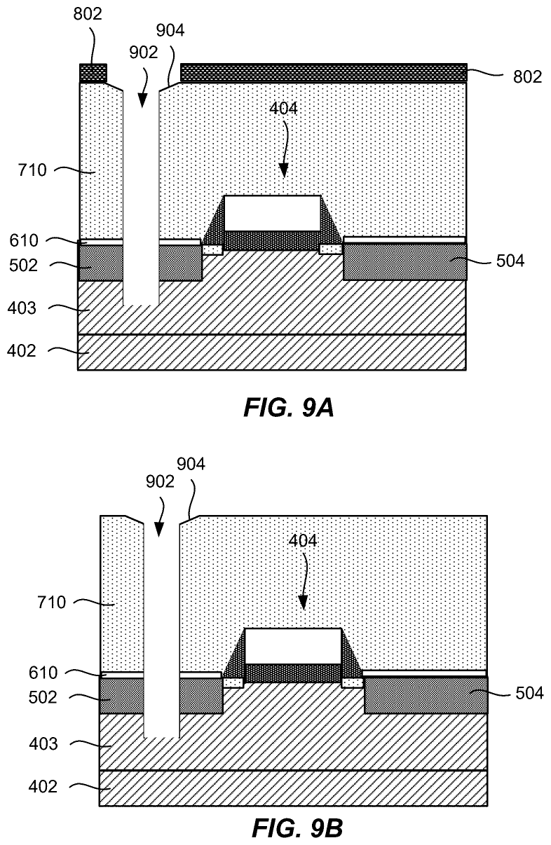

FIG. 9A is a simplified cross-sectional diagram of the LDMOS transistor at an eighth stage of fabrication according to an embodiment of the present invention. In the cross-sectional diagram illustrated in FIG. 9A, the wafer is transferred to a TCP etch tool and a second etch process is utilized to etch through the silicide layer 610 and the source region 502 into the substrate 402. During this second etch process used to extend the first opening 902, the photoresist is consumed and erodes, resulting in formation of taper 904 adjacent the top of the insulator layer 710 as the photoresist erodes. As discussed more fully below, the tapered profile will result in formation of a metal brim disposed in the tapered profile during metal (tungsten) deposition. In order to remove this tapered metal profile, additional polishing is performed and the thickness of the as-deposited insulator layer as illustrated in FIG. 7 is decreased accordingly. It should be noted that extending the first opening through the silicide layer 610 into the underlying silicon, while sufficiently deep to etch through the n+ source region and into the well region, does not extend below the well region (i.e., the p-type well) or the body region.

FIG. 9B is a simplified cross-sectional diagram of the LDMOS transistor at a ninth stage of fabrication according to an embodiment of the present invention, illustrating removal of the photoresist mask 802 illustrated in FIG. 8A.

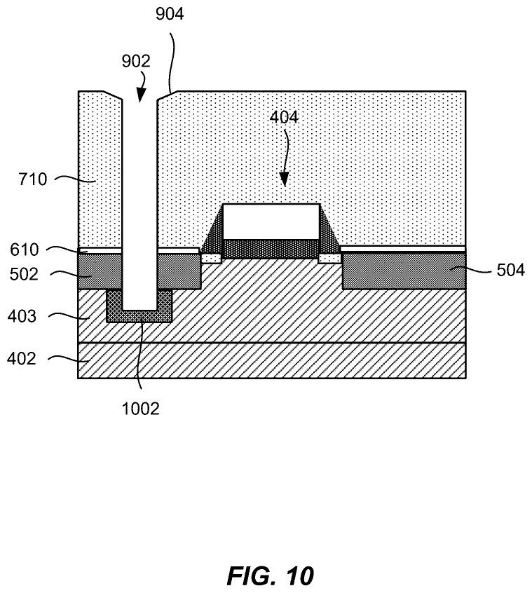

FIG. 10 is a simplified cross-sectional diagram of the LDMOS transistor at a tenth stage of fabrication according to an embodiment of the present invention. In the process illustrated in FIG. 10, a second ion implantation process is utilized to form an ohmic contact 1002 with the well region 403 in substrate 402. In some embodiments, the second ion implantation process is performed at a low enough energy as to not penetrate the dielectric film, but at a high enough dose to form a low resistance contact suitable for an ohmic contact to the well region. According to some embodiments, the ninth stage of fabrication discussed with respect to FIG. 9B may occur after the tenth stage of fabrication discussed with respect to FIG. 10.

The high dose implant provides for ohmic contact to the well as described more fully herein. In some embodiments, a low energy, high dose p+ implant is utilized and silicide layer 610 is used as the implant mask. In these embodiments, photoresist mask 802 used during the etch process that further forms the first opening 902 is removed after the etch process, for example, in a tool that includes both an etch chamber and a photoresist strip chamber. In these embodiments, the low energy of the implant enables the use of the silicide layer 610 as the implant mask and stripping of the photoresist prior to the ion implantation process.

In other embodiments, the photoresist is stripped after the ion implantation process. For example, if a higher energy implant process is utilized, photoresist mask 802 can be present during both the etch process shown in FIG. 9A as well as during the ion implantation process shown in FIG. 10. Then, photoresist mask 802 is stripped after the ion implantation process. One of ordinary skill in the art would recognize many variations, modifications, and alternatives.

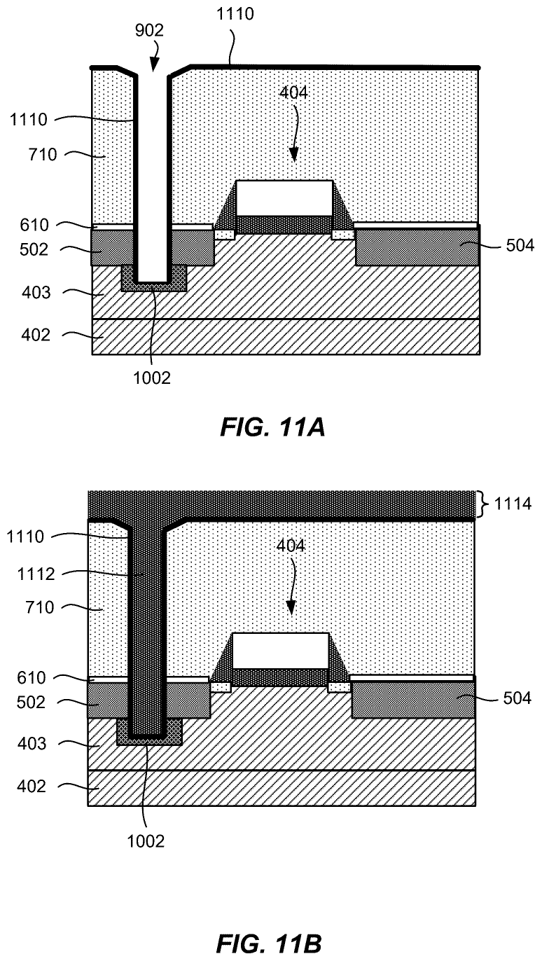

FIG. 11A is a simplified cross-sectional diagram of the LDMOS transistor at an eleventh stage of fabrication according to an embodiment of the present invention. In FIG. 11A, a deposition process is utilized to form source contact liner 1110 in first opening 902 and covering the wafer. The source contact liner 1110, together with the source contact plug discussed in relation to FIGS. 11B and 12, forms the source contact 120 illustrated in FIG. 1A.

FIG. 11B is a simplified cross-sectional diagram of the LDMOS transistor at a twelfth stage of fabrication according to an embodiment of the present invention. As illustrated in FIG. 11B, deposition of tungsten results in not only formation of the source contact plug 1112, but also deposition of a tungsten layer 1114 covering the wafer. In order to remove the tungsten layer 1114 and planarize the wafer, a CMP process is utilized as discussed in relation to FIG. 12. It should be noted that embodiments of the present invention utilize a source contact plug 1112 that passes through source region 502, thereby providing a metal material positioned between portions of source region 502. As discussed in relation to FIG. 1A, in conventional devices, a p+ implant region would be present between portions of source region 502 and in electrical contact with well region 403. In contrast, embodiments of the present invention utilize a source contact including source contact liner 1110 and source contact plug 1112 that extends through source region 502 to make contact with well region 403, thereby providing a metal between portions of the source region.

FIG. 12 is a simplified cross-sectional diagram of the LDMOS transistor at a thirteenth stage of fabrication according to an embodiment of the present invention. Referring to FIG. 12, the CMP process removes the tungsten layer 1114 illustrated in FIG. 11B as well as a portion of the as deposited insulating layer to produce polished insulating layer 1212 having a polished surface 1214 and planarized source contact 1216. As mentioned in relation to FIG. 7, the as-deposited thickness of silicide layer 610 illustrated in FIG. 7 is reduced during the CMP process that removes the brim in the tungsten, resulting in polished insulating layer 1212. Thus, after the CMP process shown in FIG. 12, a substrate with a planarized source contact 1216 is provided.

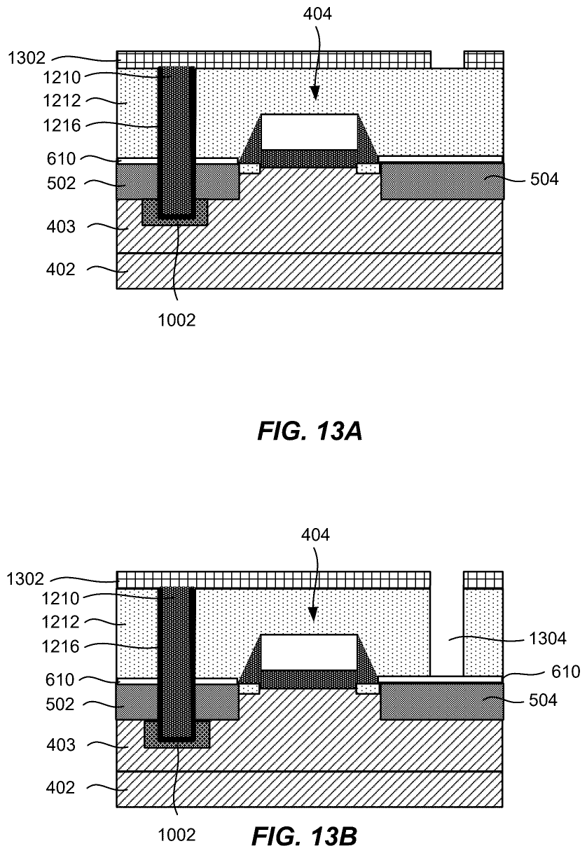

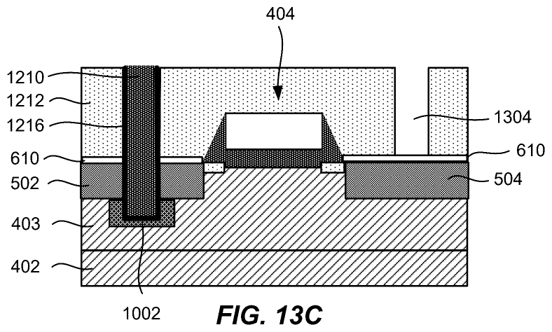

FIG. 13A is a simplified cross-sectional diagram of the LDMOS transistor at a fourteenth stage of fabrication, FIG. 13B is a simplified cross-sectional diagram of the LDMOS transistor at a fifteenth stage of fabrication, and FIG. 13C is a simplified cross sectional diagram of the LDMOS transistor at a sixteenth stage of fabrication according to an embodiment of the present invention. As shown in FIG. 13A, a photoresist layer is deposited and patterned to form drain contact mask 1302. Using the drain contact mask 1302 as shown in FIG. 13B, a second opening 1304, which can be referred to as a drain opening, is etched through the polished insulation layer 1212 to the silicide layer 610, which can serve as an etch stop. As shown in FIG. 13C, the drain contact mask 1302 can be removed after the second opening 1304 is etched.

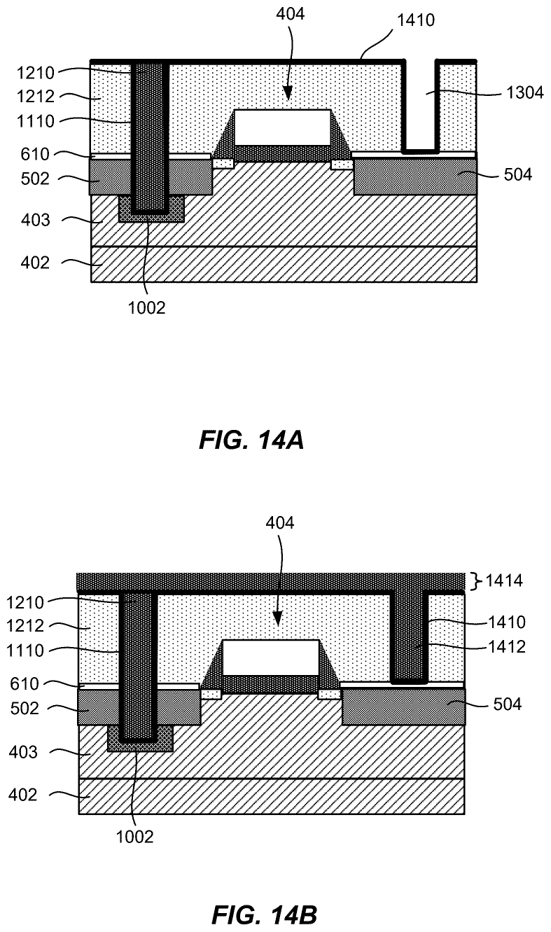

FIG. 14A is a simplified cross-sectional diagram of the LDMOS transistor at a seventeenth stage of fabrication and FIG. 14B is a simplified cross-sectional diagram of the LDMOS transistor at an eighteenth stage of fabrication according to an embodiment of the present invention. In the process flow illustrated in FIGS. 14A-14B, a drain contact is formed. Referring to FIG. 14A, a Ti/TiN liner 1410 is deposited in the second opening 1304. FIG. 14B illustrates deposition of a tungsten plug 1412 on the Ti/TiN liner 1410 filling the second opening 1304. During the deposition of the tungsten plug 1412, a layer of tungsten 1414 may be formed and subsequently removed using a CMP process.

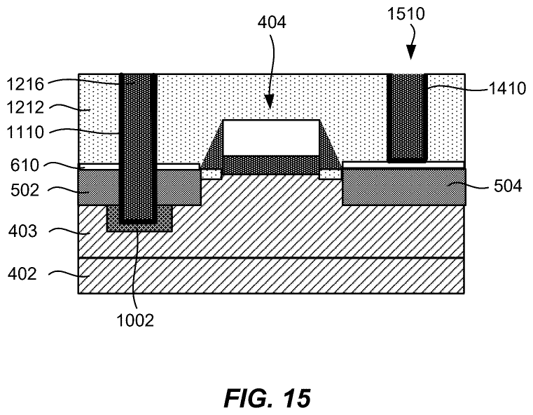

FIG. 15 is a simplified cross-sectional diagram of the LDMOS transistor at a nineteenth stage of fabrication according to an embodiment of the present invention. Referring to FIG. 15, a CMP process is utilized to remove the layer of tungsten 1414 formed on the Ti/TiN liner as well as the Ti/TiN liner 1410 formed on the photoresist, resulting in formation of drain contact 1510.

In some embodiments, the formation of the second opening 1304 and the drain contact 1510 is performed prior to the fabrication steps shown in FIGS. 8A-12, thereby forming the drain contact 1510 before formation of the source contact 1210. In other embodiments, the process flow shown above is utilized to form the source contact 1210 prior to the drain contact 1510. One of ordinary skill in the art would recognize many variations, modifications, and alternatives.

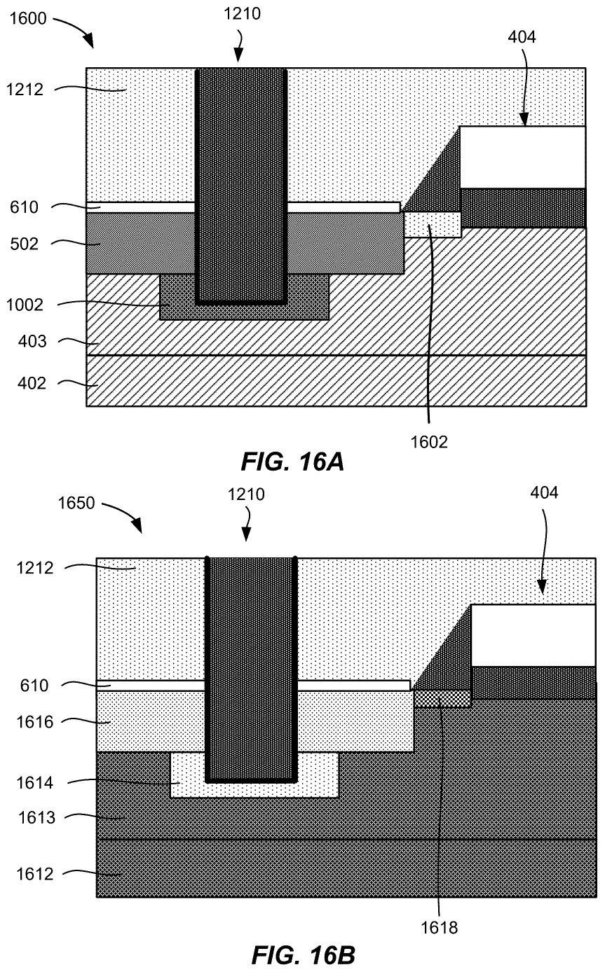

FIG. 16A is a simplified cross-sectional diagram illustrating a source contact and a gate region of an n-type LDMOS transistor according to an embodiment of the present invention. As illustrated in FIG. 16A, n-type LDMOS transistor 1600 includes source region 502 and well region 403 electrically connected by source contact 1210 passing through insulating layer 1212 and silicide layer 610. Substrate 402 and gate structure 404 is also illustrated.

In the n-type LDMOS transistor illustrated in FIG. 16A, well region 403 is p-type, ohmic contact 1002 is p-type, source region 502 is heavily doped n-type (i.e., n+) and lightly doped drain 1602 is n-type.

FIG. 16B is a simplified cross-sectional diagram illustrating a source contact and a gate region of a p-type LDMOS transistor according to an embodiment of the present invention. As illustrated in FIG. 16B, p-type LDMOS transistor 1650 includes source region 1616 and well region 1613 electrically connected by source contact 1210 passing through insulating layer 1212 and silicide layer 610. Substrate 1612 and gate structure 404 are also illustrated. The p-type LDMOS transistor 1650 illustrated in FIG. 16B may be fabricated in a similar manner to the stages of fabricating the n-type LDMOS transistor as described with respect to FIGS. 4-15, albeit with different dopant types. In the p-type LDMOS transistor 1650 illustrated in FIG. 16A, well 1613 is n-type, highly doped well contact 1614 is n-type, source region 1616 is heavily doped p-type (i.e., p+), and lightly doped drain 1618 is p-type.

It is understood that the examples and embodiments described herein are for illustrative purposes only and that various modifications or changes in light thereof will be suggested to persons skilled in the art and are to be included within the spirit and purview of this application and scope of the appended claims.

Upon reading this disclosure, those of skill in the art will appreciate still additional alternative structural and functional designs for a system and a process for motion-based content navigation through the disclosed principles herein. Thus, while particular embodiments and applications have been illustrated and described, it is to be understood that the disclosed embodiments are not limited to a precise construction and components disclosed herein. Various modification, changes and variations, which will be apparent to those skilled in the art, can be made in the arrangement, operation and details of the method and apparatus disclosed herein without departing from the spirit and scope defined in the appended claims.

What is claimed is:

1. A metal-oxide-semiconductor (MOS) transistor comprising:
a substrate including a well region;
an insulator layer coupled to the substrate;
a source including:
a source region;
a source contact passing through the insulator layer and the source region into the well region; and
an ohmic contact disposed in the well region;
a gate region including a gate insulator layer and a gate contact; and
a drain including:
a drain region; and
a drain contact passing through the insulator layer to the drain region.

2. The MOS transistor of claim 1 wherein the source region further comprises a second source contact passing through the insulator layer to the source region.

3. The MOS transistor of claim 1 wherein the source region is positioned a first predetermined distance from the substrate and the ohmic contact is positioned a second predetermined distance from the substrate less than the first predetermined distance.

4. The MOS transistor of claim 1 wherein the source region is n-type.

5. The MOS transistor of claim 1 wherein the source contact electrically connects the source region to the well region.

6. The MOS transistor of claim 1 further comprising a silicide layer disposed between the source region and the insulator layer and between the drain region and the insulator layer.

7. The MOS transistor of claim 1 wherein:
the source contact includes a source contact surface region disposed above the insulator layer; and
the drain contact includes a drain contact surface region disposed above the insulator layer.

8. The MOS transistor of claim 7 further comprising a polysilicon layer.

9. The MOS transistor of claim 1 wherein the source contact comprises:
a contact liner including titanium and titanium nitride; and
a source contact plug including tungsten.

10. A transistor array comprising:
a plurality of metal-oxide-semiconductor (MOS) transistors forming the transistor array, each of the plurality of MOS transistors including:
a source region having a source contact;
a well contact adjacent the source region, wherein the source contact electrically connects the source region and the well contact;
a gate region having a gate contact; and
a drain region having a drain contact.

11. The transistor array of claim 10 wherein each of the plurality of MOS transistors comprises a laterally diffused MOS (LDMOS) transistor.

12. The transistor array of claim 10 further comprising a metal interconnect layer electrically connecting the source contacts.

13. A method of fabricating a laterally diffused metal oxide semiconductor (LNDMOS) device, the method comprising:
providing a substrate including a well region;
forming a gate structure on the substrate;
performing a first ion implantation process to form a source region and a drain region;
forming a silicide layer on the substrate;
forming an insulation layer on the silicide layer;
etching a first opening through the insulation layer to the silicide layer;
extending the first opening to pass through the source region into the well region;
performing a second ion implantation process to form an ohmic contact to the well region;
forming a source contact in the first opening;
performing a chemical mechanical polishing (CMP) process to planarize the source contact;
etching a second opening through the insulation layer to the silicide layer; and
forming a drain contact in the second opening.

14. The method of claim 13 wherein etching the second opening further comprises:
etching through the insulation layer to the silicide layer to form a contact opening; and
forming a second source contact in the contact opening.

15. The method of claim 14 wherein:
etching the second opening and etching through the insulation layer to the silicide layer are performed concurrently; and
forming the source contact is performed prior to forming the second source contact.

16. The method of claim 13 wherein forming the source contact comprises:
depositing a contact liner in the first opening; and
depositing contact plug on the contact liner to fill the first opening.

17. The method of claim 13 wherein:
etching the first opening forms a taper region in the insulation layer; and
performing the CMP process comprises removes the taper region.

18. The method of claim 13 wherein extending the first opening passes through the silicide layer, the source region, and into the well region.

19. The method of claim 13 wherein performing the CMP process removes an upper portion of the insulating layer.

20. The method of claim 13 wherein forming the drain contact is performed after forming the source contact.
